(19) United States
(12) Patent Application Publication
(10) Pub. No.: US 2025/0204278 A1
(43) Pub. Date: Jun. 19, 2025

(54) SUPERCONDUCTING DEVICE AND METHOD FOR MANUFACTURING THE SAME

(71) Applicant: NEC Corporation, Tokyo (JP)

(72) Inventors: Satoshi TSUKIYAMA, Tokyo (JP); Katsumi KIKUCHI, Tokyo (JP); Tomohiro NISHIYAMA, Tokyo (JP)

(73) Assignee: NEC Corporation, Tokyo (JP)

(21) Appl. No.: 18/964,902

(22) Filed: Dec. 2, 2024

(30) Foreign Application Priority Data
Dec. 15, 2023 (JP) 2023-212435

(51) Int. Cl. H10N 60/81; H10N 60/01

(52) U.S. Cl. CPC H10N 60/81; H10N 60/01

(57) ABSTRACT

A superconducting device is a superconducting device using superconducting characteristics, and includes a first superconducting circuit chip that includes a functional circuit and a first metal bump, a second superconducting circuit chip that is connected to the first superconducting circuit chip and includes a second metal bump, and a diffusion barrier layer in an interface of a bonding portion of the first metal bump and the second metal bump.

### CROSS-REFERENCE TO RELATED APPLICATION

Priority is claimed on Japanese Patent Application No. 2023-212435, filed Dec. 15, 2023, the content of which is incorporated herein by reference.

### BACKGROUND ART

The present disclosure relates to a superconducting device and a method for manufacturing the same.

PCT International Publication No. WO2017/105524 (hereinafter referred to as Patent Document 1) discloses a technique related to a bump bond that connects first and second quantum chips each including a functional circuit.

The bump bond has a configuration in which a first bump pad provided on a first chip side and made of, for example, aluminum (Al) and a second bump pad provided on a second chip side and made of, for example, indium (In) are pressure-bonded to each other.

In the bump pads, a material having superconductivity such as niobium (Ni) or tin (Sn) is used in addition to Al and In described above.

### SUMMARY

In the bump bond described in Patent Document 1 described above, in a case where different metals are employed for the first bump pad and the second bump pad, an intermetallic compound between dissimilar metals may occur in bonding surfaces of the bump pads.

While a material having superconductivity is employed for both the first and second bump pads, it is not always true that the intermetallic compound has similar superconductivity to the material having superconductivity.

Since the intermetallic compound is likely to have various characteristics according to conditions (including a history of change in pressure/temperature before and after pressure bonding as well as during pressure bonding) such as a temperature, a pressure, and the like during pressure bonding, for example, even in a case where the intermetallic compound has superconductivity, it is not easy to suppress variation of the superconducting characteristics to within a predetermined range.

An example object of the present disclosure is to suppress the generation of intermetallic compounds to a bump bond that is used for connection of a plurality of superconducting chips configuring a superconducting device.

A superconducting device according to an example aspect of the present disclosure is a superconducting device using superconducting characteristics, the superconducting device including a first superconducting circuit chip that includes a functional circuit and a first metal bump, a second superconducting circuit chip that is connected to the first superconducting circuit chip and includes a second metal bump, and a diffusion barrier layer in an interface of a bonding portion of the first metal bump and the second metal bump.

A method for manufacturing a superconducting device according to an example aspect of the present disclosure is a method for manufacturing a superconducting device using superconducting characteristics, the method including preparing a first superconducting circuit chip that includes a functional circuit and a first metal bump, and a second superconducting circuit chip that includes a second metal bump, and forming a diffusion barrier layer in an interface of a bonding portion of the first metal bump and the second metal bump.

### BRIEF DESCRIPTION OF THE DRAWINGS

FIG. 1 is a cross-sectional view of a superconducting device according to the present disclosure.

FIG. 2 is a cross-sectional view showing the superconducting device according to the present disclosure separately for each member.

FIG. 3 is a cross-sectional view illustrating Modification Example 1 of a bump pad of the superconducting device of FIG. 2.

FIG. 4 is a cross-sectional view illustrating Modification Example 2 of a bump pad of the superconducting device of FIG. 2.

FIG. 5 is a cross-sectional view of a state before processing in Modification Example 3 of a bump pad of the superconducting device of FIG. 2.

FIG. 6 is a cross-sectional view of a state after processing in Modification Example 3 of the bump pad of the superconducting device of FIG. 2.

FIG. 7 is a cross-sectional view of a superconducting device according to the present disclosure.

FIG. 8 is a cross-sectional view of a superconducting device according to the present disclosure.

FIG. 9 is a cross-sectional view of a superconducting device according to the present disclosure.

FIG. 10 is a cross-sectional view of a superconducting device according to the present disclosure.

FIG. 11A is an end view illustrating a modification example of a cross-sectional shape of a metal bump according to the present disclosure.

FIG. 11B is an end view illustrating a modification example of a cross-sectional shape of a metal bump according to the present disclosure.

FIG. 11C is an end view illustrating a modification example of a cross-sectional shape of a metal bump according to the present disclosure.

FIG. 12 is a table illustrating characteristics of a forming material of a diffusion barrier layer that is used in the present disclosure.

### EXAMPLE EMBODIMENT

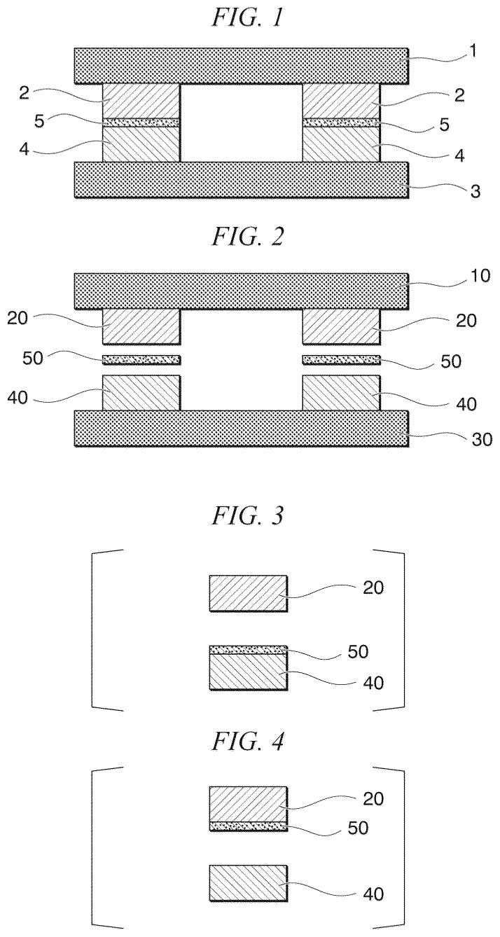

A superconducting device of some example embodiments according to the present disclosure will be described with reference to FIG. 1.

The superconducting device is a superconducting device using superconducting characteristics, and has a characteristic that a diffusion barrier layer 5 is formed in an interface of a bonding portion of a first metal bump 2 formed in a first superconducting circuit chip 1 provided with a functional circuit and a second metal bump 4 formed in a second superconducting circuit chip 3 connected to the first superconducting circuit chip 1.

According to the above-described configuration, in bonding the first superconducting circuit chip 1 and the second superconducting circuit chip 3 to perform bump bonding, since the diffusion barrier layer 5 is interposed between a first metal bump 2 and a second metal bump 4 pressure-bonded to each other, it is possible to prevent diffusion of molecules between a metal material forming the first metal bump 2 and a metal material forming the second metal bump 4.

Accordingly, it is possible to suppress the generation of an intermetallic compound between the first metal bump 2 and the second metal bump 4 to suppress reduction or variation of superconductivity due to the generation of an intermetallic compound in a bump bond using the first metal bump 2 and the second metal bump 4.

A method for manufacturing a superconducting device of some example embodiments according to the present disclosure is a method for manufacturing a superconducting device using superconducting characteristics, the method including a step of forming a diffusion barrier layer 5 in an interface of a bonding portion of the first metal bump 2 formed in the first superconducting circuit chip 1 provided with the functional circuit and the second metal bump 4 formed in the second superconducting circuit chip 3 connected to the first superconducting circuit chip 1.

According to the above-described configuration, it is possible to form the diffusion barrier layer 5 for preventing diffusion of metals forming the first metal bump 2 and the second metal bump 4 between the first metal bump 2 and the second metal bump 4 between a step of making the first superconducting circuit chip 1 and the second superconducting circuit chip 3 face each other and a step of pressure-bonding the first metal bump 2 and the second metal bump 4 to each other between the first superconducting circuit chip 1 and the second superconducting circuit chip 3, and it is possible to suppress the generation of an intermetallic compound in a bump bond in which the first metal bump 2 and the second metal bump 4 are integrated, to suppress reduction or variation of superconductivity.

Some example embodiments according to the present disclosure will be described with reference to FIGS. 2 to 6.

FIG. 2 illustrates a superconducting device of some example embodiments according to the present disclosure, and the superconducting device has a basic configuration in which a first metal bump 20 is provided on a lower surface of a first superconducting circuit chip 10 provided with a functional circuit (including an interposer having a superconductive conductor circuit for connection to a circuit board or the like as well as a logic circuit) using superconducting characteristics, a second metal bump 40 is provided on an upper surface of a second superconducting circuit chip 30 connected to the functional circuit of the first superconducting circuit chip 10 and provided with a functional circuit using superconducting characteristics, and a diffusion barrier layer 50 for preventing diffusion of metal molecules between dissimilar metals is provided between the first metal bump 20 and the second metal bump 40.

FIG. 2 illustrates a state that the above-described elements configuring the superconducting device are separated before bonding integrally for convenience of description, and for example, an integrated superconducting device as illustrated in FIG. 1 is configured by pressure-bonding the elements to each other vertically (a facing direction of the first and second superconducting circuit chips 10 and 30 and an up-down direction of FIG. 2).

The first metal bump 20 and the second metal bump 40 are bump pads that are bonded integrally to establish a bump bond, and are made of, for example, niobium (Nb), aluminum (Al), tin (Sn), or indium (In). In the example illustrated in the drawing, the first metal bump 20 and the second metal bump 40 have a transverse section in a circular shape, and have a tip formed flat. In the some example embodiments described above, Al is used as a material for the first metal bump 20, and In is used as a material for the second metal bump 40. That is, in the some example embodiments described above, the first and second metal bumps 20 and 40 are made of dissimilar metals.

The diffusion barrier layer 50 is made of an inorganic material such as metals including aluminum (Al) and indium (In), a compound thereof, or a silicon (Si) oxide film, or an organic material, and has the same planar shape as the cross sections (tip surface) of the first and second metal bumps 20 and 40.

More specifically, examples of the material that can be used for the diffusion barrier layer 50 include a metal oxide such as an aluminum oxide, an indium oxide, a niobium oxide, a titanium oxide, a tin oxide, a tantalum oxide, or a silicon oxide, an oxide of a semimetal, a metal nitride such as an aluminum nitride, an indium nitride, a titanium nitride, a tin nitride, a tantalum nitride, or a silicon nitride, a nitride of a semimetal, an oxynitride such as a silicon oxynitride or a titanium oxynitride, or other ceramics. An organic resin material such as epoxy, phenol, acryl, urethane, styrene, polyimide, or polyamide may be used.

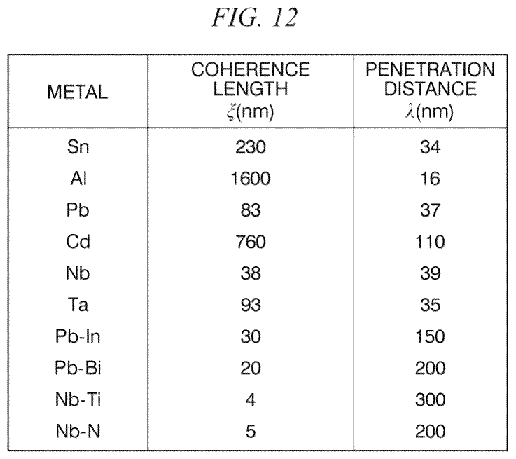

The thickness of the diffusion barrier layer 50 needs to be set to a thickness not greater than a coherence length of a forming material to secure superconductivity equal to or greater than that of the metals forming the first and second metal bumps 20 and 40. The coherence length of the material that can be employed in the diffusion barrier layer 50 is, for example, as in a table illustrated in FIG. 12.

The thickness of the diffusion barrier layer 50 is set to a thickness (a dimension in the up-down direction of FIG. 2 or the like) not greater than a coherence length ξ at which an upper critical magnetic field H that is calculated by Expression (1) shown below to implement a superconducting state can be obtained, according to materials in the table illustrated in FIG. 12.

$$H = {φ}_{0} / π {ξ}^{2} \qquad ( 1 )$$

Note that φ₀ is 2.0678×10⁻¹⁵T·m² [tesla-square meter].

That is, as illustrated in Expression (1), since the upper critical magnetic field H is in reverse proportion to the square of the coherence length ξ, the thickness of the diffusion barrier layer 50 is set to be equal to or less than the value at which the upper critical magnetic field His equal to or greater than a desired value in the superconducting state.

The diffusion barrier layer 50 is not limited to a member separated from the first and second metal bumps 20 and 40, and may have a configuration in which the diffusion barrier layer 50 is formed integrally at the tip of the second metal bump 40 and is pressure-bonded to the upper first metal bump 20 in this state, as Modification Example 1 illustrated in FIG. 3.

As Modification Example 2 illustrated in FIG. 4, a configuration may be made in which the diffusion barrier layer 50 is formed integrally at the tip of the first metal bump 20 and is pressure-bonded to the lower second metal bump 40 in this state.

As illustrated in Modification Examples 1 and 2, as a method for forming the diffusion barrier layer within a predetermined range (a range of contact during pressure-bonding) of the first and second metal bumps 20 and 40, a method for forming a compound to be a diffusion barrier layer in only a predetermined region of a metal material (a region of the tip of the first metal bump 20 to be left as a diffusion barrier layer 50A) where an oxide film or the like does not occur on a surface is generally used.

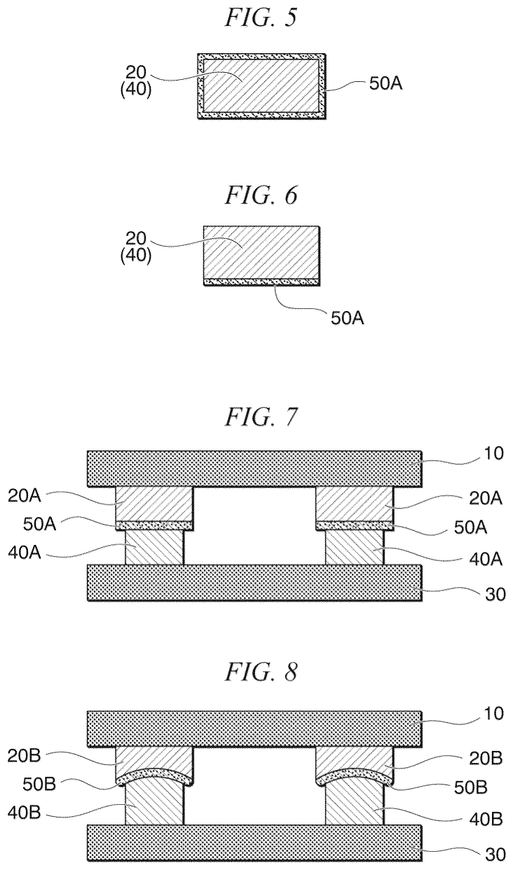

Other than the general method, as Modification Example 3 illustrated in FIGS. 5 and 6, a method for removing a part (an outer peripheral portion excluding an end surface) of the diffusion barrier layer 50A covering the entire surface of the first (or second) metal bump 20 (40) to leave the diffusion barrier layer 50A in only a bonding surface of the first (or second) metal bump 20 (40) may be employed.

More specifically, a method for removing an oxide film on the outer periphery of the first or second metal bump 20 (40) made of Al of which the surface is covered with an oxide film (diffusion barrier layer) 50A due to contact with the atmosphere, by machining or chemical processing under a non-oxidizing environment such as vacuum chamber or an inert gas chamber to leave a part as the diffusion barrier layer 50A as in FIG. 6 may be employed.

In a case where the first (or second) metal bump 20 (40) is not formed of a metal material having a characteristic of generating an oxide film in the atmosphere, a material to be the first (or second) metal bump 20 (40) may be placed in a gaseous oxidizing atmosphere, may be immersed in an oxidizing liquid, or may be applied an oxidizing liquid to the surface.

With this, the oxide film (diffusion barrier layer) 50A as illustrated in FIG. 5 may be formed, and a part of the oxide film 50A may be removed to form the diffusion barrier layer 50A at only the tip of the first (or second) metal bump 20 (40).

FIG. 7 illustrates some example embodiments according to the present disclosure. In FIG. 7, components common to FIGS. 2 to 6 are represented by the same reference numbers, and description will be simplified.

In the some example embodiments according to the present disclosure, the first metal bump 20A is formed to have a diameter greater than the second metal bump 40A (a shape in which a circular shape of a transverse section has a large diameter). Also in the present example embodiments, it is assumed that Al is employed for the first metal bump 20A, and In having a melting point lower than Al is employed for the second metal bump 40A.

Similarly to the some example embodiments described above, the thickness of the diffusion barrier layer 50A is set to a predetermined value to satisfy having the required superconductivity in consideration of the coherence length intrinsic to the material.

According to the configuration of the present example embodiments, the first metal bump 20A is formed to have a diameter greater than the second metal bump 40A.

With this, in pressure-bonding the first and second metal bumps 20A and 40A in an up-down direction of FIG. 7, it is possible to cope with even a case where the tip of the second metal bump 40A having a low melting point is deformed (such that the diameter is widened) due to pressure-bonding.

That is, according to this configuration, the diameter of the diffusion barrier layer 50A at the tip of the first metal bump 20A is large.

For this reason, in pressure-bonding the first and second metal bumps 20A and 40A, the relatively low melting point metal (In) forming the second metal bump 40A is melted or deformed but does not easily flow around an outer peripheral surface (a surface on which the diffusion barrier layer 50A is not formed) of the first metal bump 20A.

Accordingly, it is possible to more reliably prevent a phenomenon that the metal forming the second metal bump 40A comes into contact with the metal forming the first metal bump 20A and is diffused on the outer peripheral surface of the first metal bump 20A, and an intermetallic compound is formed between the metals.

FIG. 8 illustrates some example embodiments according to the present disclosure. In FIG. 8, components common to FIGS. 2 to 7 are represented by the same reference numbers, and description will be simplified.

In the present example embodiments, similarly to the some example embodiments described above, the first metal bump 20B is formed to have a diameter greater than the second metal bump 40B (a shape in which a circular shape of a transverse section has a large diameter).

In the present example embodiments, a surface of a lower end (diffusion barrier layer 50B) of the first metal bump 20B is made to be a concave surface, and the tip of the second metal bump 40B is made to be a convex surface corresponding to the concave surface (in a cross section illustrated in FIG. 8, while the tip of the second metal bump 40B is expressed in a curve line, but in a three-dimensional manner, the tip of the second metal bump 40B is a curved surface having a radius of curvature corresponding to the diffusion barrier layer 50B). Also in the present example embodiments, it is assumed that Al is employed for the first metal bump 20B, and In having a melting point lower than Al is employed for the second metal bump 40B.

The thickness of the diffusion barrier layer 50B is set to a predetermined value to have superconductivity similar to that of the some example embodiments described above.

According to the configuration of the present example embodiments, the first metal bump 20B is formed to have a diameter greater than the second metal bump 40B.

With this, in pressure-bonding first and second metal bumps 20B (40B) in an up-down direction of FIG. 8, it is possible to cope with a case where the tip of the second metal bump 40B having a low melting point is deformed (such that the diameter is widened) due to pressure-bonding.

That is, according to this configuration, the diameter of the diffusion barrier layer 50B at the tip of the first metal bump 20B is large. In addition, the diffusion barrier layer 50B is made to be a concave surface to cover the surface of the second metal bump.

For this reason, in pressure-bonding the first and second metal bumps 20B and 40B, the relatively low melting point metal (In) forming the second metal bump 40B does not easily flow around an outer peripheral surface (a surface where the diffusion barrier layer 50B is not formed) of the first metal bump 20B.

Accordingly, it is possible to more reliably prevent a phenomenon that the metal forming the second metal bump 40B comes into contact with the metal forming the first metal bump 20B to form an intermetallic compound.

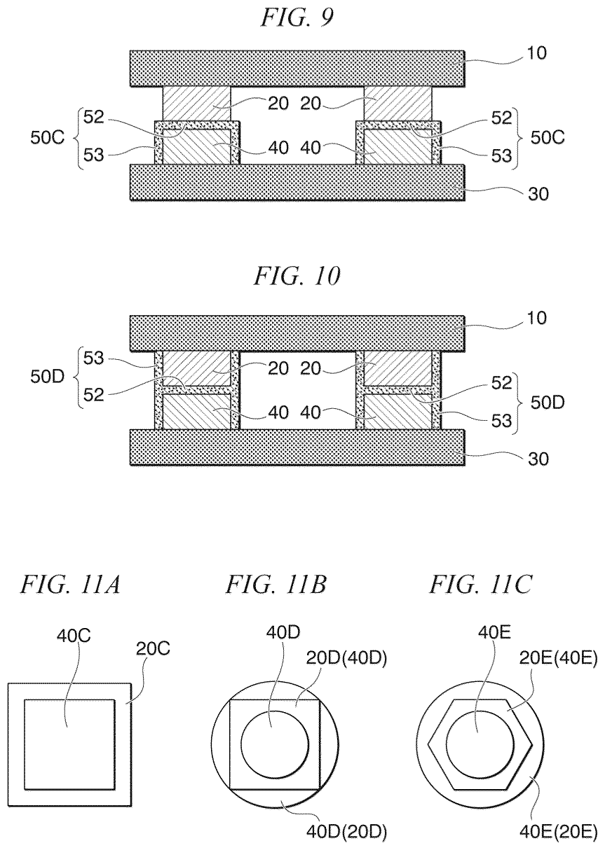

FIG. 9 illustrates some example embodiments according to the present disclosure. In FIG. 9, components common to FIGS. 2 to 8 are represented by the same reference numbers, and description will be simplified.

The present example embodiments have a configuration in which an upper surface of the tip (an upper end of FIG. 9) and an outer periphery of the second metal bump 40 are covered with a diffusion barrier layer 50C. The diffusion barrier layer 50C has a shape in which a tip of a cylindrical portion 53 covering an outer periphery of an end portion of the second metal bump 40 is covered with a planar portion 52 integrated with the cylindrical portion 53. The planar portion 52 is formed at a thickness having predetermined superconductivity similarly to the some example embodiments described above.

In the present example embodiments, the entire tip of the second metal bump 40 is covered with the diffusion barrier layer 50C. For this reason, in pressure-bonding the first and second metal bumps 20 and 40, the metal forming the second metal bump 40 does not come into contact with the metal forming the first metal bump 20. Accordingly, it is possible to prevent the generation of an intermetallic compound due to contact of the first and second metal bumps 20 and 40.

The diffusion barrier layer 50C may be provided in the first metal bump 20 instead of the second metal bump 40 or may be formed in both the first and second metal bumps 20 and 40.

With this configuration, it is possible to more reliably prevent the generation of an intermetallic compound due to diffusion of metals between the first and second metal bumps 20 and 40 compared to the example of FIG. 8.

FIG. 10 illustrates some example embodiments according to the present disclosure. In FIG. 10, components common to FIGS. 2 to 9 are represented by the same reference numbers, and a description will be simplified.

In the present example embodiments, a superconducting device has a configuration in which the tips of the first and second metal bumps 20 and 40 are covered with a diffusion barrier layer 50D.

The diffusion barrier layer 50D includes a cylindrical portion 53 that covers the entire outer peripheries of the first and second metal bumps 20 and 40, and a planar portion 52 that is formed integrally with the cylindrical portion 53 and is disposed between the first and second metal bumps 20 and 40.

The cylindrical portion 53 has a cylindrical shape that covers the outer peripheries of the first and second metal bumps 20 and 40, and the planar portion 52 is disposed to cross the cylindrical portion 53.

With the diffusion barrier layer 50D, it is possible to prevent direct contact of the first and second metal bumps 20 and 40 to prevent the generation of an intermetallic compound between the first and second metal bumps 20 and 40.

In the some example embodiments described above, while the cross sections (end surface) of the first and second metal bumps 20 and 40 or the like have a circular shape, the cross sections of the first and second metal bumps 20 and 40 or the like are not limited to a perfect circle, and may be shapes illustrated in FIGS. 11A to 11C.

FIG. 11A illustrates a first modification example where a first metal bump 20C is formed in a square shape having a length of a side greater than that of a second metal bump 40C.

FIG. 11B illustrates a second modification example where a first metal bump 20D is formed in a square shape and a second metal bump 40D is formed in a circular shape having a diameter smaller than an inscribed circle of the square shape, and a third modification example where the second metal bump 40D is formed in the square shape and the first metal bump 20D is formed in a circular shape having a diameter greater than a circumscribed circle of the square shape.

FIG. 11C illustrates a fourth modification example where a first metal bump 20E is formed in a hexagonal shape and a second metal bump 40E is formed in a circular shape having a diameter smaller than an inscribed circle of the hexagonal shape, and a fifth modification example where the second metal bump 40E is formed in the hexagonal shape and the first metal bump 20E is formed in a circular shape having a diameter greater than a circumscribed circle of the hexagonal shape.

In the first to fifth modification examples, similarly to the some example embodiments described above, it is possible to prevent the generation of an intermetallic compound by covering the tip surfaces of the first metal bumps 20C to 20E and/or the second metal bumps 40C to 40E with the diffusion barrier film having the same shape.

In regard to the shapes of the first and second metal bumps illustrated in the first to fifth modification examples, it is desirable to select an appropriate shape according to a shape of a conductor pad or a shape of a conductor pattern of a superconducting circuit chip to which the metal bump is to be bonded.

A material that can be used as the first metal bump 20 (20A to 20E) and the second metal bump 40 (40A to 40E) is, for example, tin (Sn), niobium (Nb), bismuth (Bi), yttrium (Y), or lead (Pb), in addition to the indium (In), aluminum (Al), or an alloy thereof employed in the some example embodiments described above.

The number of bump portions, the disposition, the forming materials, the shapes of the bump portions, and a combination thereof are not limited to the some example embodiments described above.

While the some example embodiments of the present disclosure have been described in detail with reference to the drawings, specific configurations should not be limited to these example embodiments, and the present invention should include design changes and the like within the scope without departing from the gist of the present disclosure. Then, each example embodiment can be combined with other example embodiments as appropriate.

In the some example embodiments of the present disclosure, while the configuration can also be used in a device (quantum device) using a quantum-mechanical phenomenon or a superconducting device using a chip (quantum chip) in which a circuit using a quantum-mechanical phenomenon is incorporated, the present disclosure is not limited thereto.

According to the present disclosure, it is possible to suppress the generation of an intermetallic compound due to bonding of the first and second metal bumps.

A part or the whole of the some example embodiments described above can be described as the following supplementary notes, but is not limited to aspects specified by the supplementary notes.

### (Supplementary Note 1)

A superconducting device using superconducting characteristics, the superconducting device including
a first superconducting circuit chip that includes a functional circuit and a first metal bump,
a second superconducting circuit chip that is connected to the first superconducting circuit chip and includes a second metal bump, and
a diffusion barrier layer in an interface of a bonding portion of the first metal bump and the second metal bump.

### (Supplementary Note 2)

The superconducting device according to Supplementary Note 1,
in which the first metal bump and the second metal bump contain a superconducting material.

### (Supplementary Note 3)

The superconducting device according to Supplementary Note 2,
in which a thickness of the diffusion barrier layer is equal to or less than a coherence length of the first and second metal bumps.

### (Supplementary Note 4)

The superconducting device according to Supplementary Note 2 or 3,
in which the first metal bump consists of at least any one of indium, aluminum, tin, niobium, bismuth, yttrium, lead, or an alloy of at least any one of indium, aluminum, tin, niobium, bismuth, yttrium, or lead, and
in which the second metal bump consists of at least any one of indium, aluminum, tin, niobium, bismuth, yttrium, lead, or an alloy of at least any one of indium, aluminum, tin, niobium, bismuth, yttrium, or lead.

### (Supplementary Note 5)

The superconducting device according to any one of Supplementary Notes 1 to 4,
in which the diffusion barrier layer contains niobium.

### (Supplementary Note 6)

The superconducting device according to any one of Supplementary Notes 1 to 5,
in which the first metal bump and the second metal bump are different in shape.

### (Supplementary Note 7)

The superconducting device according to any one of Supplementary Notes 1 to 6,
in which a cross section of each of the first and second metal bumps has a circular shape, and
in which a diameter of the cross section of the second metal bump is smaller than a diameter of the cross section of the first metal bump.

### (Supplementary Note 8)

The superconducting device according to any one of Supplementary Notes 1 to 7,
wherein a first surface of the first metal bump faces a second surface of the second metal bump, and
in which one of the first surface and the second surface is convex, and the other of the first surface and the second surface is concave.

### (Supplementary Note 9)

The superconducting device according to any one of Supplementary Notes 1 to 8,
in which the diffusion barrier layer is provided in at least a part of bonding surfaces of the first metal bump and the second metal bump or at least a part of side surfaces of the first metal bump and the second metal bump.

### (Supplementary Note 10)

The superconducting device according to any one of Supplementary Notes 1 to 9,
in which a material contained the first metal bump and a material contained the second metal bump are different.

### (Supplementary Note 11)

The superconducting device according to any one of Supplementary Notes 1 to 3,
in which the diffusion barrier layer contains a metal oxide, an oxide of a semimetal, a metal nitride, a nitride of a semimetal, an oxynitride, a ceramic, or an organic resin material.

### (Supplementary Note 12)

A method for manufacturing a superconducting device using superconducting characteristics, the method including
preparing a first superconducting circuit chip that includes a functional circuit and a first metal bump, and a second superconducting circuit chip that includes a second metal bump, and
forming a diffusion barrier layer in an interface of a bonding portion of the first metal bump and the second metal bump.

### (Supplementary Note 13)

The method according to Supplementary Note 12,
in which the forming of the diffusion barrier layer includes interposing the diffusion barrier layer in a region in at least one of the first metal bump or the second metal bump to be brought into pressure contact with the other of the first metal bump and the second metal bump.

### (Supplementary Note 14)

The method according to Supplementary Note 12,
in which the forming of the diffusion barrier layer includes removing an oxide film formed on a surface of at least one of the first metal bump or the second metal bump in a region excluding bonding surfaces of the first metal bump and the second metal bump.

### (Supplementary Note 15)

The method according to Supplementary Note 12,
in which the forming of the diffusion barrier layer includes forming an oxide film in bonding surfaces of the first metal bump and the second metal bump on a surface of at least one of the first metal bump or the second metal bump, the surface being not covered with an oxide film.

What is claimed is:

1. A superconducting device using superconducting characteristics, the superconducting device comprising:
a first superconducting circuit chip that includes a functional circuit and a first metal bump;
a second superconducting circuit chip that is connected to the first superconducting circuit chip and includes a second metal bump; and
a diffusion barrier layer in an interface of a bonding portion of the first metal bump and the second metal bump.

2. The superconducting device according to claim 1,
wherein the first metal bump and the second metal bump contain a superconducting material.

3. The superconducting device according to claim 2,
wherein a thickness of the diffusion barrier layer is equal to or less than a coherence length of the first and second metal bumps.

4. The superconducting device according to claim 2,
wherein the first metal bump consists of at least any one of indium, aluminum, tin, niobium, bismuth, yttrium, lead, or an alloy of at least any one of indium, aluminum, tin, niobium, bismuth, yttrium, or lead, and
wherein the second metal bump consists of at least any one of indium, aluminum, tin, niobium, bismuth, yttrium, lead, or an alloy of at least any one of indium, aluminum, tin, niobium, bismuth, yttrium, or lead.

5. The superconducting device according to claim 1,
wherein the diffusion barrier layer contains niobium.

6. The superconducting device according to claim 1,
wherein the first metal bump and the second metal bump are different in shape.

7. The superconducting device according to claim 1,
wherein a cross section of each of the first and second metal bumps has a circular shape, and
wherein a diameter of the cross section of the second metal bump is smaller than a diameter of the cross section of the first metal bump.

8. The superconducting device according to claim 1,
wherein a first surface of the first metal bump faces a second surface of the second metal bump, and
wherein one of the first surface and the second surface is convex, and the other of the first surface and the second surface is concave.

9. The superconducting device according to claim 1,
wherein the diffusion barrier layer is provided in at least a part of bonding surfaces of the first metal bump and the second metal bump or at least a part of side surfaces of the first metal bump and the second metal bump.

10. The superconducting device according to claim 1,
wherein a material contained the first metal bump and a material contained the second metal bump are different.

11. The superconducting device according to claim 1,
wherein the diffusion barrier layer contains a metal oxide, an oxide of a semimetal, a metal nitride, a nitride of a semimetal, an oxynitride, a ceramic, or an organic resin material.

12. A method for manufacturing a superconducting device using superconducting characteristics, the method comprising:
preparing a first superconducting circuit chip that includes a functional circuit and a first metal bump, and a second superconducting circuit chip that includes a second metal bump; and
forming a diffusion barrier layer in an interface of a bonding portion of the first metal bump and the second metal bump.

13. The method according to claim 12,
wherein the forming of the diffusion barrier layer includes interposing the diffusion barrier layer in a region in at least one of the first metal bump or the second metal bump to be brought into pressure contact with the other of the first metal bump and the second metal bump.

14. The method according to claim 12,
wherein the forming of the diffusion barrier layer includes removing an oxide film formed on a surface of at least one of the first metal bump or the second metal bump in a region excluding bonding surfaces of the first metal bump and the second metal bump.

15. The method according to claim 12,
wherein the forming of the diffusion barrier layer includes forming an oxide film in bonding surfaces of the first metal bump and the second metal bump on a surface of at least one of the first metal bump or the second metal bump, the surface being not covered with an oxide film.
